(19) United States
(12) Patent Application Publication
(10) Pub. No.: US 2023/0187850 A1
(43) Pub. Date: Jun. 15, 2023

(54) LIQUID METAL CONNECTION DEVICE AND METHOD

(71) Applicant: Intel Corporation, Santa Clara, CA (US)

(72) Inventors: Ziyin Lin, Chandler, AZ (US); Aaron Michael Garelick, Chandler, AZ (US); Karumbu Meyyappan, Portland, OR (US); Gregorio Murtagian, Phoenix, AZ (US); Srikant Nekkanty, Chandler, AZ (US); Taylor Rawlings, Hillsboro, OR (US); Jeffory L. Smalley, East Olympia, WA (US); Pooya Tadayon, Portland, OR (US); Dingying Xu, Chandler, AZ (US)

(21) Appl. No.: 17/549,427

(22) Filed: Dec. 13, 2021

(51) Int. Cl. H01R 3/08; H01L 23/498; H01L 23/32; H01R 43/00

(52) U.S. Cl. CPC H01R 3/08; H01L 23/49816; H01L 23/32; H01L 23/49833; H01R 43/005

(57) ABSTRACT

An electronic device and associated methods are disclosed. In one example, the electronic device includes a socket that includes one or more liquid metal filled reservoirs. In selected examples, the electronic devices and sockets include configurations to aid in reducing ingress of moisture.

### TECHNICAL FIELD

Embodiments described herein generally relate electronic devices, such as semiconductor devices and socketing interconnect technologies.

### BACKGROUND

Liquid metal interconnect array sockets provide a number of advantages, including, but not limited to the ability to de-socket a device and socket in a new device at room temperature with minimal or no tooling. In some cases, liquid metal can interact with moisture in the air, which may alter the liquid metal. It is desired to have device configurations and methods that address these concerns, and other technical challenges.

### BRIEF DESCRIPTION OF THE DRAWINGS

FIG. 1 shows an electronic device and interconnect socket in accordance with some example embodiments.

FIG. 2 shows another electronic device and interconnect socket in accordance with some example embodiments.

FIG. 3A shows another electronic device and interconnect socket in accordance with some example embodiments.

FIG. 3B shows another electronic device and interconnect socket in accordance with some example embodiments.

FIG. 3C shows another electronic device and interconnect socket in accordance with some example embodiments.

FIG. 4A-4C show another electronic device and interconnect socket in accordance with some example embodiments.

FIG. 5 shows another electronic device and interconnect socket in accordance with some example embodiments.

FIG. 6 shows another electronic device and interconnect socket in accordance with some example embodiments.

FIG. 7A-7B show another electronic device and interconnect socket in accordance with some example embodiments.

FIG. 8 shows a flow diagram of a method of socketing an electronic device in accordance with some example embodiments.

FIG. 9 shows a system that may incorporate an electronic device and socket and associated methods, in accordance with some example embodiments.

### DESCRIPTION OF EMBODIMENTS

The following description and the drawings sufficiently illustrate specific embodiments to enable those skilled in the art to practice them. Other embodiments may incorporate structural, logical, electrical, process, and other changes. Portions and features of some embodiments may be included in, or substituted for, those of other embodiments. Embodiments set forth in the claims encompass all available equivalents of those claims.

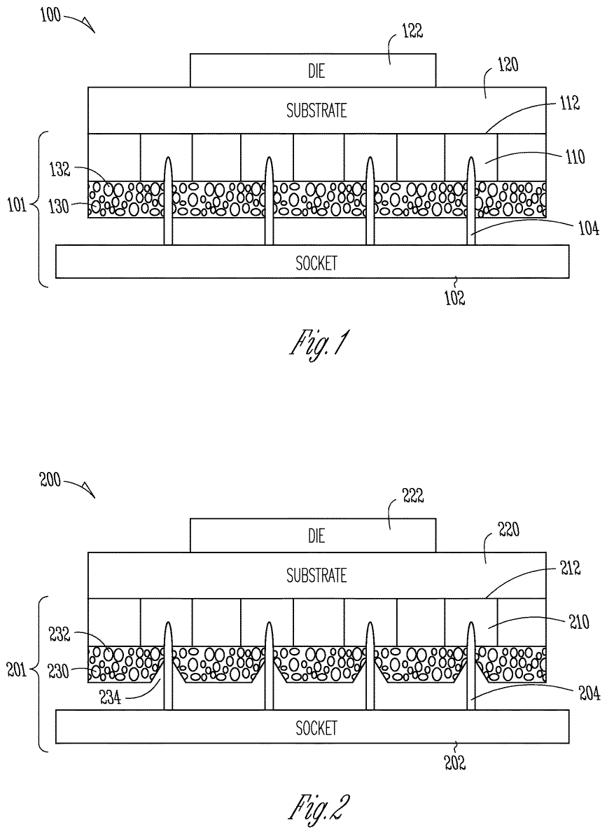

FIG. 1 shows an electronic device 100 according to one example. The electronic device 100 includes a semiconductor die 122 coupled to a first side of a package substrate 120. The electronic device 100 includes a socket 101 that is coupled to a second side of the package substrate 120.

The socket 101 includes an array of pins 104 on a first surface 102. The socket 101 further includes an array of liquid metal filled reservoirs 110 on a second surface 112. In one example, the liquid metal filled reservoirs 110 include gallium or a gallium alloy. Gallium and gallium alloys can be tailored by varying alloying elements and element amounts to be liquid at room temperature. Metals that are liquid at room temperature are useful because they easily form an electrical connection when a solid metal mating component penetrates the liquid metal. Example solid metal components include, but are not limited to, pins, rods, plates, or other geometries. Notably, this type of liquid metal electrical connection is easily made, and easily disconnected with minimal force.

Although FIG. 1 shows the array of pins 104 on a bottom surface, and the array of liquid metal filled reservoirs 110 coupled to the package substrate 120, the invention is not so limited. One of ordinary skill in the art, having the benefit of the present disclosure, will recognize that locations of the array of pins 104 and the array of liquid metal filled reservoirs 110 can be reversed, with the array of pins 104 instead coupled to the package substrate 120. Similar interchanges of positions of described halves of sockets can also be made with other examples described below.

The example of FIG. 1 further shows a cap layer 130 including porous resilient material regions covering the array of liquid metal filled reservoirs. In the example shown in FIG. 1, pores 132 are substantially uniformly distributed within a continuous cap layer 130. Other example cap layers may include specific regions of porous resilient material located only in correspondence to pins 104, as described in more detail in subsequent examples. In one example, the cap layer 130 includes closed cell pores. In one example, the cap layer 130 includes open cell pores. Closed cell pores may be more resistant to ingress of moisture through the cap layer 130. Open cell pores may exhibit a lower insertion force of pins 104. Both properties are desirable, and may be balanced depending on a desired weighting of each property for a given product configuration. Examples of cap layer 130 materials include, but are not limited to, resilient materials, polymers, elastomers in general, specific elastomers such as polyimides, silicones, polyurethanes, fluoroelastomers, polyolefins, etc.

The pins in the array of pins include a pin cross section dimension. In a cylindrical pin example, a pin cross section dimension is a pin diameter. In other examples, a pin may be formed from substantially flat material, which may result in a rectangular or square pin cross section dimension. In such an example, the pin cross section dimension may be defined as a diagonal dimension across the rectangle or square. Other pin cross section dimensions will depend on a pin cross section geometry, and will be determined by a greatest dimension across a pin cross section.

In one example, pores 132 in the porous resilient material have a diameter larger than a pin cross section dimension. When pores are smaller than a pin cross section dimension, an insertion force to drive the pin 104 through the cap layer 130 becomes large, and a possibility for tearing the cap layer 130 instead of piercing the cap layer 130 exists. In contrast, when the pores are larger than the pin cross section dimension, insertion force is small, and a smooth pierce is achieved when driving the pins 104 into and through the cap layer 130.

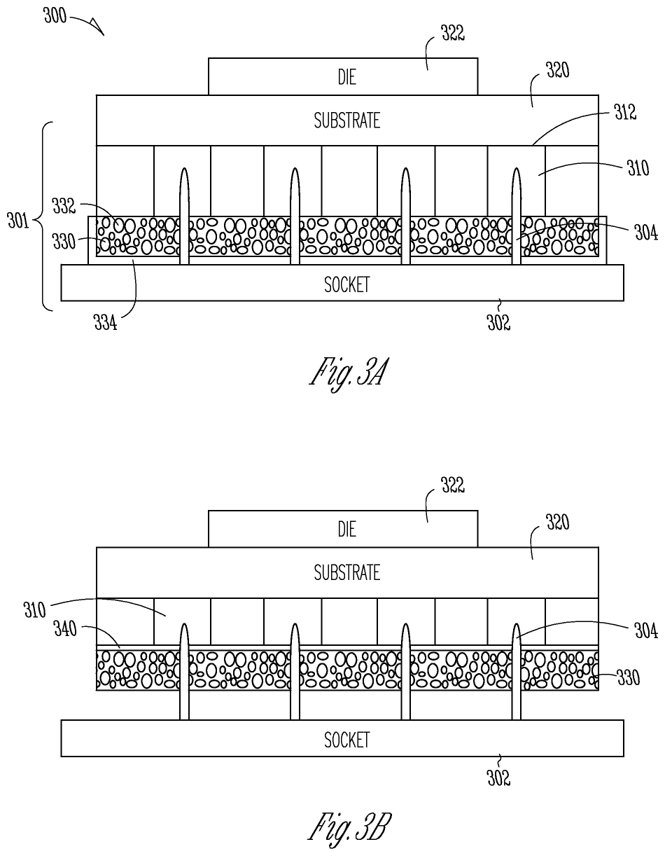

FIG. 2 shows another example of an electronic device 200. The electronic device 200 includes a semiconductor die 222 coupled to a first side of a package substrate 220. The electronic device 200 includes a socket 201 that is coupled to a second side of the package substrate 220. The socket 201 includes an array of pins 204 on a first surface 202. The socket 201 further includes an array of liquid metal filled reservoirs 210 on a second surface 212. The example of FIG. 2 further shows a cap layer 230 including porous resilient material regions covering the array of liquid metal filled reservoirs.

The example of FIG. 2 further shows one or more a strain relief features 234 in the porous resilient material. Inclusion of a strain relief feature 234 or an array of strain relief features 234 will reduce an insertion force of the pins 204 as they pierce the cap layer 230. In the example shown in FIG. 2, the strain relief feature 234 includes a “V” notch, however the invention is not so limited. Other geometries, such as a pre-cut slit, a hemisphere notch, a square recess, etc. are also within the scope of the invention.

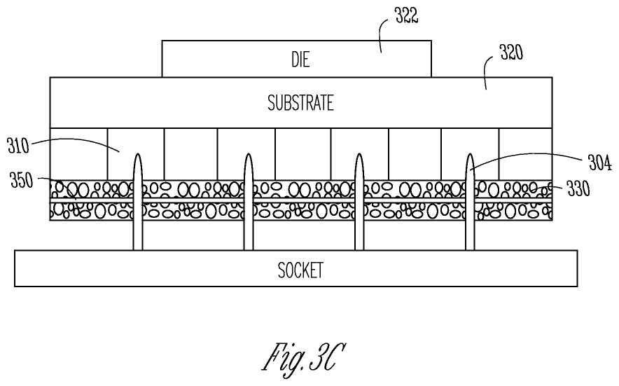

FIG. 3A shows another example of an electronic device 300. The electronic device 300 includes a semiconductor die 322 coupled to a first side of a package substrate 320. The electronic device 300 includes a socket 301 that is coupled to a second side of the package substrate 320. The socket 301 includes an array of pins 304 on a first surface 302. The socket 301 further includes an array of liquid metal filled reservoirs 310 on a second surface 312. The example of FIG. 3A further shows a cap layer 330 including porous resilient material regions covering the array of liquid metal filled reservoirs.

The example of FIG. 3A further shows a continuous moisture barrier layer 334 over the cap layer 330. In one example, the continuous moisture barrier layer 334 is a resilient layer. In one example, the moisture barrier layer is on a bottom surface of the cap layer 330. In one example, the moisture barrier layer is on side surfaces of the cap layer 330. In one example, the moisture barrier layer is on both a bottom surface, and side surfaces of the cap layer 330. Examples of resilient materials include, but are not limited to, polymers, elastomers in general, specific elastomers such as polyimides, silicones, polyurethanes, fluoroelastomers, polyolefins, etc. If moisture is able to migrate from an ambient environment into the liquid metal filled reservoirs 310, a reaction with the moisture may cause snaking or clumping of the liquid metal, which may reduce the reliability of the electrical connection with the pin 304. The addition of the continuous moisture barrier layer 334 over the cap layer 330 further reduces a permeability to moisture and reduces any reactions with the liquid metal. In one example, resilient materials as described above may be used in more than one structure of the present disclosure, including, but not limited to, cap layer 330, other examples of cap layers (130, 230, etc.), barrier layer 334, barrier layer 742, resilient material 740, 440, etc.

FIG. 3B shows another example of an electronic device similar to device 300 from FIG. 3A. The electronic device includes a semiconductor die 322 coupled to a first side of a package substrate 320. The electronic device 300 includes a socket as described with respect to FIG. 3A, including an array of liquid metal filled reservoirs 310. The example of FIG. 3B further shows a cap layer 330 including porous resilient material regions covering the array of liquid metal filled reservoirs. In the example of FIG. 3B, an adhesive layer 340 is included at an interface between the cap layer 330 and the liquid metal filled reservoirs 310. In FIG. 3C, an adhesive layer 350 is included within a middle portion of the cap layer 330. The inclusion of an adhesive layer can provide a method of attachment (as shown in FIG. 3B). Additionally, the inclusion of an adhesive layer modulates puncture and moisture diffusion behaviors with respect to the pin 304. Examples of adhesives for the adhesive layers (340, 350) include, but are not limited to, epoxy based adhesives, acrylic, polyurethanes, etc.

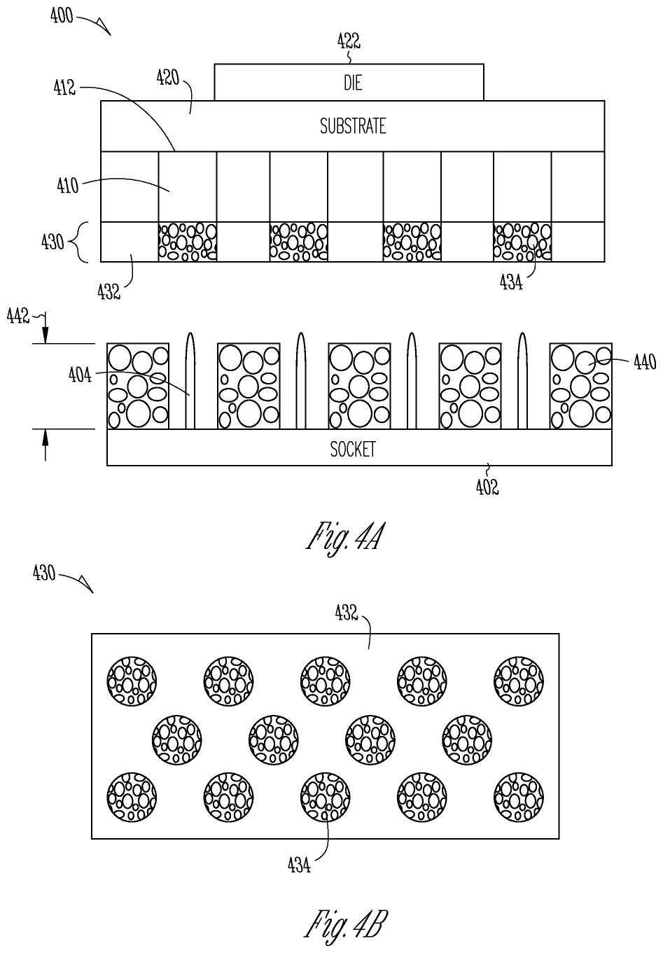

FIGS. 4A-4C shown another example of an electronic device 400. The electronic device 400 includes a semiconductor die 422 coupled to a first side of a package substrate 420. The electronic device 300 includes a socket that is coupled to a second side of the package substrate 320. The socket includes an array of pins 404 on a first surface 402. The socket further includes an array of liquid metal filled reservoirs 410 on a second surface 412. The example of FIG. 4A further shows a cap layer 430 including porous resilient material regions 434 covering the array of liquid metal filled reservoirs.

In the example of FIGS. 4A-4C, the cap layer 430 includes a continuous solid portion 432 with isolated resilient material regions 434 corresponding to the array of liquid metal filled reservoirs 410. Minimizing a surface area of the resilient material regions 434 helps to reduce ingress of moisture through the cap layer 430 and into the liquid metal filled reservoirs 410. Examples of solid portion 432 include, but are not limited to, solid polymers, metal, glass, ceramic, etc. In one example, openings in a pre-formed continuous solid portion 432 are filled with an uncured polymer and a foaming agent. The foaming agent forms porous resilient material regions 434 as shown in FIG. 4B.

The example of FIG. 4A further shows an opposing resilient material 440 located on the first surface 402. In one example, the resilient material 440 includes a porous resilient material 440. In one example, the porous resilient material 440 includes a closed cell structure. In one example, the porous resilient material 440 includes an open cell structure. In one example, the resilient material 440 is only located in regions between pins 404. In one example, the resilient material 440 is continuous, and encases the pins 404. The resilient material 440 is shown having a thickness 442 in an uncompressed state.

FIG. 4C shows the electronic device 400 after socketing the pins 404 through the cap layer 430, and into the liquid metal filled reservoirs 410. As illustrated in FIG. 4C, the resilient material 440 is compressed to a second thickness 442. In one example, the compression results in a sealing force pressing up against the cap layer 430. This provides a tight seal that reduces unwanted ingress of moisture to the resilient material regions 434 and into the liquid metal filled reservoirs 410. Additionally, compression of the resilient material 440 may reduce an air volume of pores which further reduces a permeability to moisture. The sealing force may also aid in de-socketing for any potential replacement of the die 422 and package substrate 420 at a later date.

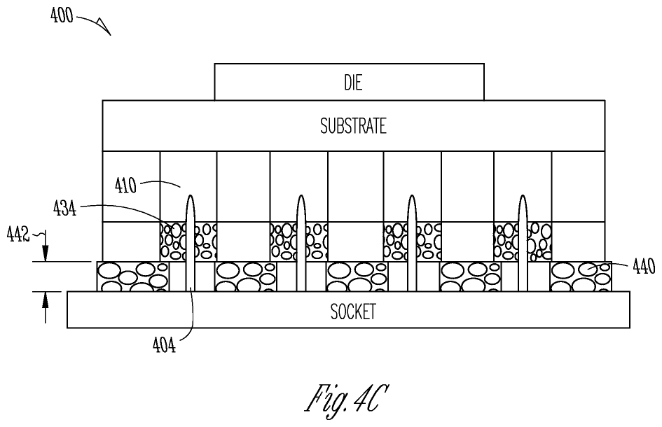

FIG. 5 shows another example of an electronic device 500. The electronic device 500 includes a semiconductor die 522 coupled to a first side of a package substrate 520. The electronic device 500 includes a socket 501 that is coupled to a second side of the package substrate 520. The socket 501 includes an array of pins 504 on a first surface 502. The socket 501 further includes an array of liquid metal filled reservoirs 510 on a second surface 512. The example of FIG. 5 further shows a cap layer 530 including porous resilient material regions covering the array of liquid metal filled reservoirs.

The example of FIG. 5 further shows a moisture barrier layer 540 on lateral edges of the cap layer 530. In one example, the moisture barrier layer 540 is rigid. In one example, the moisture barrier layer 540 is resilient. The addition of the moisture barrier layer 540 on lateral edges of the cap layer 530 provides a seal that reduces unwanted ingress of moisture to the cap layer 530 and into the liquid metal filled reservoirs 510.

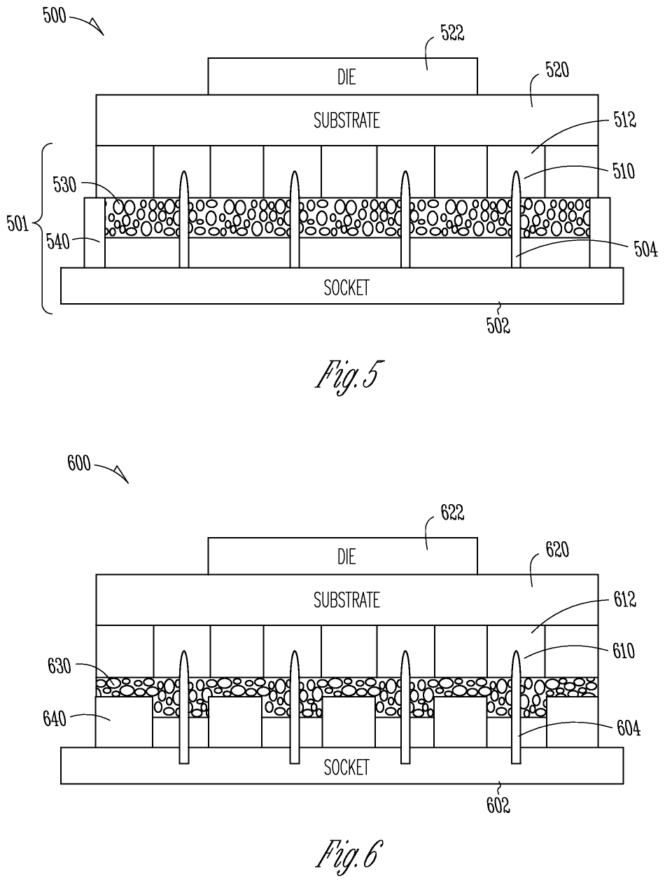

FIG. 6 shows another example of an electronic device 600. The electronic device 600 includes a semiconductor die 622 coupled to a first side of a package substrate 620. The electronic device 600 includes a socket 601 that is coupled to a second side of the package substrate 620. The socket 601 includes an array of pins 604 on a first surface 602. The socket 601 further includes an array of liquid metal filled reservoirs 610 on a second surface 612. The example of FIG. 6 further shows a cap layer 630 including porous resilient material regions covering the array of liquid metal filled reservoirs.

The example of FIG. 6 further shows an array of rigid protrusions 640 between pins in the array of pins 604, the array of rigid protrusions 640 configured to compress mating portions of the cap layer 630 when socketed. Similar to the example of FIG. 4, compression results in a sealing force pressing up against the cap layer 630. This provides a tight seal that reduces unwanted ingress of moisture to the resilient material regions 634 and into the liquid metal filled reservoirs 610. Additionally, compression of the resilient material 640 may reduce an air volume of pores which further reduces a permeability to moisture. The sealing force may also aid in de-socketing for any potential replacement of the die 622 and package substrate 620 at a later date.

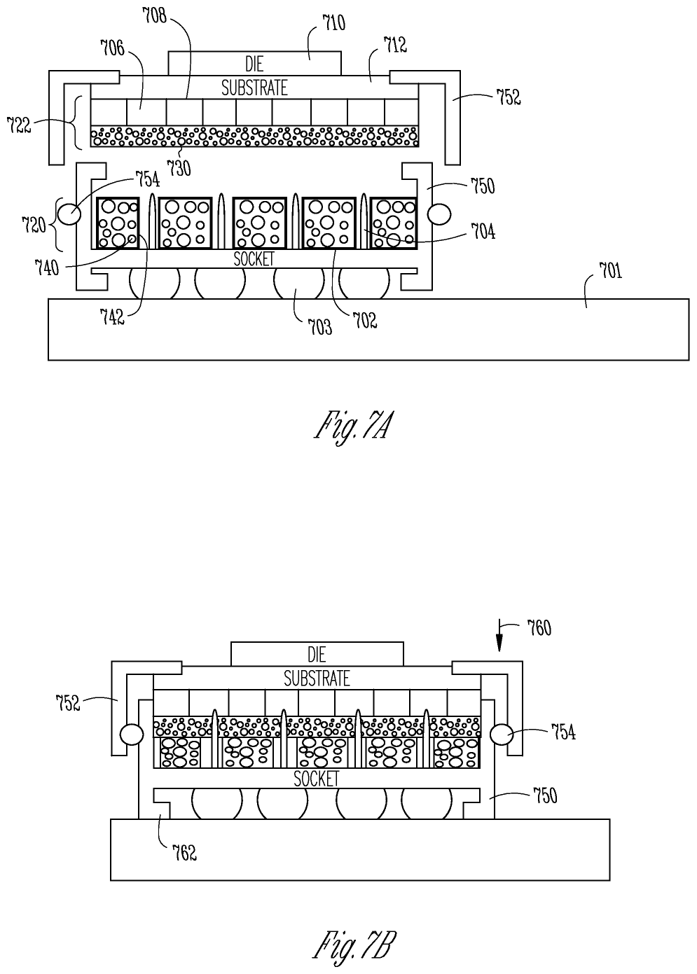

FIGS. 7A and 7B show another example of an electronic device 700. The electronic device 700 includes a semiconductor die 710 coupled to a first side of a package substrate 712. The electronic device 700 includes a second half 722 of a socket that is coupled to a second side of the package substrate 712. The electronic device 700 includes a first half 720 of a socket that includes an array of pins 704 on a first surface 702. The socket further includes an array of liquid metal filled reservoirs 706 on a second surface 708. The example of FIG. 7A further shows a cap layer 730 including porous resilient material regions covering the array of liquid metal filled reservoirs. An opposing resilient material 740 is further shown located on the first surface 702. In one example, the resilient material 740 includes a porous resilient material. In one example a continuous moisture barrier layer 742 is further included over the resilient material 740.

The example of FIGS. 7A and 7B further show a first fence 750 located on lateral edges of the first surface 702. A second fence 752 is further shown located on lateral edges of the second surface 708. As shown in FIG. 7B, the first fence 750 and the second fence 752 slidably fit within each other to form a moisture barrier when socketed. In one example, an o-ring 754 is included to improve the seal. Other examples do not use an o-ring, and rely on a tight interference fit between the first fence 750 and the second fence 752 to form the seal.

In the example of FIGS. 7A and 7B, compression of the resilient material 740 also forms a moisture barrier in addition to the first and second fences 750, 752. In one example, the first fence 750 is vertically movable with respect to the first surface 702. As shown in FIG. 7B, upon the application of pressure 760, the first fence 750 slides downward with respect to the first surface 702 and forms a seal against a circuit board 701 connected to the first socket half 720 to form a moisture barrier between the first socket half 720 and the circuit board 701. This prevents any ingress of moisture that may enter past solder balls 703 and into the first socket half 720.

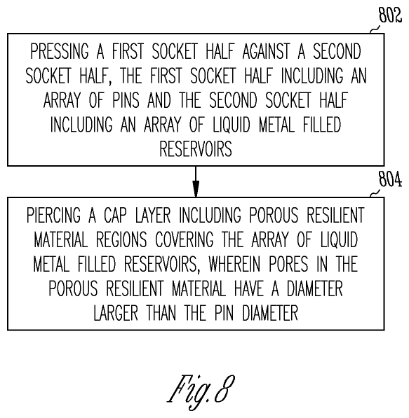

FIG. 8 shows a flow diagram of a method of socketing an electronic device according to one example. In operation 802, a first socket half is pressed together with a second socket half, the first socket half including an array of pins and the second socket half including an array of liquid metal filled reservoirs. In operation 804, a cap layer is pierced, the cap layer including porous resilient material regions covering the array of liquid metal filled reservoirs, wherein pores in the porous resilient material have a diameter larger than a pin cross section dimension.

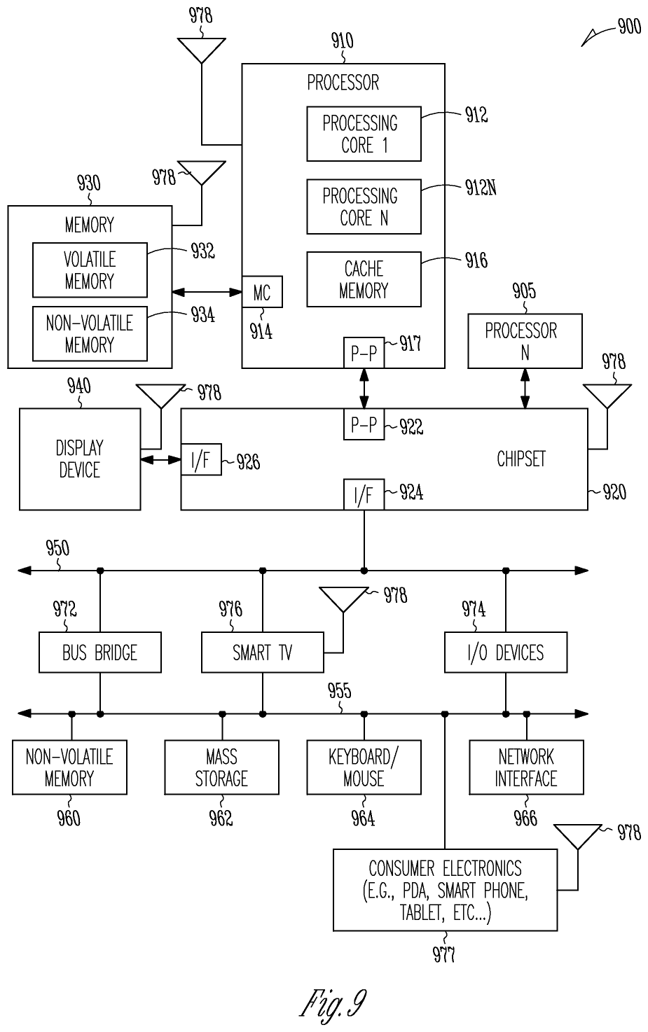

FIG. 9 illustrates a system level diagram, depicting an example of an electronic device (e.g., system) that may include a socket and electronic devices and/or methods described above. In one embodiment, system 900 includes, but is not limited to, a desktop computer, a laptop computer, a netbook, a tablet, a notebook computer, a personal digital assistant (PDA), a server, a workstation, a cellular telephone, a mobile computing device, a smart phone, an Internet appliance or any other type of computing device. In some embodiments, system 900 includes a system on a chip (SOC) system.

In one embodiment, processor 910 has one or more processor cores 912 and 912N, where 912N represents the Nth processor core inside processor 910 where N is a positive integer. In one embodiment, system 900 includes multiple processors including 910 and 905, where processor 905 has logic similar or identical to the logic of processor 910. In some embodiments, processing core 912 includes, but is not limited to, pre-fetch logic to fetch instructions, decode logic to decode the instructions, execution logic to execute instructions and the like. In some embodiments, processor 910 has a cache memory 916 to cache instructions and/or data for system 900. Cache memory 916 may be organized into a hierarchal structure including one or more levels of cache memory.

In some embodiments, processor 910 includes a memory controller 914, which is operable to perform functions that enable the processor 910 to access and communicate with memory 930 that includes a volatile memory 932 and/or a non-volatile memory 934. In some embodiments, processor 910 is coupled with memory 930 and chipset 920. Processor 910 may also be coupled to a wireless antenna 978 to communicate with any device configured to transmit and/or receive wireless signals. In one embodiment, an interface for wireless antenna 978 operates in accordance with, but is not limited to, the IEEE 802.11 standard and its related family, Home Plug AV (HPAV), Ultra Wide Band (UWB), Bluetooth, WiMax, or any form of wireless communication protocol.

In some embodiments, volatile memory 932 includes, but is not limited to, Synchronous Dynamic Random Access Memory (SDRAM), Dynamic Random Access Memory (DRAM), RAMBUS Dynamic Random Access Memory (RDRAM), and/or any other type of random access memory device. Non-volatile memory 934 includes, but is not limited to, flash memory, phase change memory (PCM), read-only memory (ROM), electrically erasable programmable read-only memory (EEPROM), or any other type of non-volatile memory device.

Memory 930 stores information and instructions to be executed by processor 910. In one embodiment, memory 930 may also store temporary variables or other intermediate information while processor 910 is executing instructions. In the illustrated embodiment, chipset 920 connects with processor 910 via Point-to-Point (PtP or P-P) interfaces 917 and 922. Chipset 920 enables processor 910 to connect to other elements in system 900. In some embodiments of the example system, interfaces 917 and 922 operate in accordance with a PtP communication protocol such as the Intel® QuickPath Interconnect (QPI) or the like. In other embodiments, a different interconnect may be used.

In some embodiments, chipset 920 is operable to communicate with processor 910, 905N, display device 940, and other devices, including a bus bridge 972, a smart TV 976, I/O devices 974, nonvolatile memory 960, a storage medium (such as one or more mass storage devices) 962, a keyboard/mouse 964, a network interface 966, and various forms of consumer electronics 977 (such as a PDA, smart phone, tablet etc.), etc. In one embodiment, chipset 920 couples with these devices through an interface 924. Chipset 920 may also be coupled to a wireless antenna 978 to communicate with any device configured to transmit and/or receive wireless signals. In one example, any combination of components in a chipset may be separated by a continuous flexible shield as described in the present disclosure.

Chipset 920 connects to display device 940 via interface 926. Display 940 may be, for example, a liquid crystal display (LCD), a light emitting diode (LED) array, an organic light emitting diode (OLED) array, or any other form of visual display device. In some embodiments of the example system, processor 910 and chipset 920 are merged into a single SOC. In addition, chipset 920 connects to one or more buses 950 and 955 that interconnect various system elements, such as I/O devices 974, nonvolatile memory 960, storage medium 962, a keyboard/mouse 964, and network interface 966. Buses 950 and 955 may be interconnected together via a bus bridge 972.

In one embodiment, mass storage device 962 includes, but is not limited to, a solid state drive, a hard disk drive, a universal serial bus flash memory drive, or any other form of computer data storage medium. In one embodiment, network interface 966 is implemented by any type of well-known network interface standard including, but not limited to, an Ethernet interface, a universal serial bus (USB) interface, a Peripheral Component Interconnect (PCI) Express interface, a wireless interface and/or any other suitable type of interface. In one embodiment, the wireless interface operates in accordance with, but is not limited to, the IEEE 802.11 standard and its related family, Home Plug AV (HPAV), Ultra Wide Band (UWB), Bluetooth, WiMax, or any form of wireless communication protocol.

While the modules shown in FIG. 9 are depicted as separate blocks within the system 900, the functions performed by some of these blocks may be integrated within a single semiconductor circuit or may be implemented using two or more separate integrated circuits. For example, although cache memory 916 is depicted as a separate block within processor 910, cache memory 916 (or selected aspects of 916) can be incorporated into processor core 912.

To better illustrate the method and apparatuses disclosed herein, a non-limiting list of embodiments is provided here:

Example 1 includes an electronic interconnect socket. The socket includes an array of pins on a first surface, the pins having a pin cross section dimension, an array of liquid metal filled reservoirs on a second surface, and a cap layer including porous resilient material regions covering the array of liquid metal filled reservoirs, wherein pores in the porous resilient material have a diameter larger than the pin cross section dimension.

Example 2 includes the electronic interconnect socket of example 1, further including a strain relief pattern in the porous resilient material.

Example 3 includes the electronic interconnect socket of any one of examples 1-2, wherein the cap layer is formed from a continuous porous resilient material.

Example 4 includes the electronic interconnect socket of any one of examples 1-3, wherein the cap layer includes a continuous solid portion with isolated resilient material regions corresponding to the array of liquid metal filled reservoirs.

Example 5 includes the electronic interconnect socket of any one of examples 1-4, further including a continuous moisture barrier layer over the cap layer.

Example 6 includes the electronic interconnect socket of any one of examples 1-5, further including an adhesive layer between the cap layer and the array of liquid metal filled reservoirs.

Example 7 includes the electronic interconnect socket of any one of examples 1-6, further including an adhesive layer within a middle portion of the cap layer.

Example 8 includes the electronic interconnect socket of any one of examples 1-7, wherein the liquid metal includes gallium.

Example 9 includes an electronic device. The electronic device includes a semiconductor die coupled to a first side of a substrate, and an electronic interconnect socket on a second side of the substrate. The electronic interconnect socket includes an array of pins on a first surface, an array of liquid metal filled reservoirs on a second surface, a cap layer including porous resilient material regions covering the array of liquid metal filled reservoirs, and a seal between the first surface and the second surface.

Example 10 includes the electronic device of example 9, wherein the seal includes an opposing porous resilient material located on the first surface.

Example 11 includes the electronic device of any one of examples 9-10, wherein the opposing porous resilient material includes a closed cell porous material.

Example 12 includes the electronic device of any one of examples 9-11, wherein the seal includes a moisture barrier layer on lateral edges of the cap layer.

Example 13 includes the electronic device of any one of examples 9-12, wherein the seal includes an array of rigid protrusions between pins in the array of pins, the array of rigid protrusions configured to compress mating portions of the cap layer when socketed.

Example 14 includes the electronic device of any one of examples 9-13, wherein the seal includes a first fence located on lateral edges of the first surface and a second fence located on lateral edges of the second surface, wherein the first fence and the second fence slidably fit within each other to form a moisture barrier when socketed.

Example 15 includes the electronic device of any one of examples 9-14, further including an array of solder balls coupled to the array of pins though the first surface.

Example 16 includes the electronic device of any one of examples 9-15, wherein the first fence is vertically movable with respect to the first surface.

Example 17 includes the electronic device of any one of examples 9-16, further including an o-ring between the first fence and the second fence when socketed.

Example 18 includes a method of socketing an electronic device. The method includes pressing a first socket half together with a second socket half, the first socket half including an array of pins and the second socket half including an array of liquid metal filled reservoirs, and piercing a cap layer including porous resilient material regions covering the array of liquid metal filled reservoirs, wherein pores in the porous resilient material have a diameter larger than a pin cross section dimension.

Example 19 includes the method of example 18, further including compressing a portion of the porous resilient material to selectively reduce a moisture permeability.

Example 20 includes the method of any one of examples 18-19, further including compressing a portion of a second porous resilient material interspersed within the array of pins.

Example 21 includes the method of any one of examples 18-20, further including vertically sliding a first fence that surrounds the first socket half to seal against a circuit board connected to the first socket half to form a moisture barrier between the first socket half and the circuit board.

Example 22 includes the method of any one of examples 18-21, further including vertically sliding a second fence that surrounds the second socket half to mate with the first fence to form a moisture barrier between the first socket half and the second socket half.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein.

Although an overview of the inventive subject matter has been described with reference to specific example embodiments, various modifications and changes may be made to these embodiments without departing from the broader scope of embodiments of the present disclosure. Such embodiments of the inventive subject matter may be referred to herein, individually or collectively, by the term “invention” merely for convenience and without intending to voluntarily limit the scope of this application to any single disclosure or inventive concept if more than one is, in fact, disclosed.

The embodiments illustrated herein are described in sufficient detail to enable those skilled in the art to practice the teachings disclosed. Other embodiments may be used and derived therefrom, such that structural and logical substitutions and changes may be made without departing from the scope of this disclosure. The Detailed Description, therefore, is not to be taken in a limiting sense, and the scope of various embodiments is defined only by the appended claims, along with the full range of equivalents to which such claims are entitled.

As used herein, the term “or” may be construed in either an inclusive or exclusive sense. Moreover, plural instances may be provided for resources, operations, or structures described herein as a single instance. Additionally, boundaries between various resources, operations, modules, engines, and data stores are somewhat arbitrary, and particular operations are illustrated in a context of specific illustrative configurations. Other allocations of functionality are envisioned and may fall within a scope of various embodiments of the present disclosure. In general, structures and functionality presented as separate resources in the example configurations may be implemented as a combined structure or resource. Similarly, structures and functionality presented as a single resource may be implemented as separate resources. These and other variations, modifications, additions, and improvements fall within a scope of embodiments of the present disclosure as represented by the appended claims. The specification and drawings are, accordingly, to be regarded in an illustrative rather than a restrictive sense.

The foregoing description, for the purpose of explanation, has been described with reference to specific example embodiments. However, the illustrative discussions above are not intended to be exhaustive or to limit the possible example embodiments to the precise forms disclosed. Many modifications and variations are possible in view of the above teachings. The example embodiments were chosen and described in order to best explain the principles involved and their practical applications, to thereby enable others skilled in the art to best utilize the various example embodiments with various modifications as are suited to the particular use contemplated.

It will also be understood that, although the terms “first,” “second,” and so forth may be used herein to describe various elements, these elements should not be limited by these terms. These terms are only used to distinguish one element from another. For example, a first contact could be termed a second contact, and, similarly, a second contact could be termed a first contact, without departing from the scope of the present example embodiments. The first contact and the second contact are both contacts, but they are not the same contact.

The terminology used in the description of the example embodiments herein is for the purpose of describing particular example embodiments only and is not intended to be limiting. As used in the description of the example embodiments and the appended examples, the singular forms “a,” “an,” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

As used herein, the term “if” may be construed to mean “when” or “upon” or “in response to determining” or “in response to detecting,” depending on the context. Similarly, the phrase “if it is determined” or “if [a stated condition or event] is detected” may be construed to mean “upon determining” or “in response to determining” or “upon detecting [the stated condition or event]” or “in response to detecting [the stated condition or event],” depending on the context.

1. An electronic interconnect socket, comprising:
an array of pins on a first surface, the pins having a pin cross section dimension;
an array of liquid metal filled reservoirs on a second surface; and
a cap layer including porous resilient material regions covering the array of liquid metal filled reservoirs, wherein pores in the porous resilient material have a diameter larger than the pin cross section dimension.

2. The electronic interconnect socket of claim 1, further including a strain relief pattern in the porous resilient material.

3. The electronic interconnect socket of claim 1, wherein the cap layer is formed from a continuous porous resilient material.

4. The electronic interconnect socket of claim 1, wherein the cap layer includes a continuous solid portion with isolated resilient material regions corresponding to the array of liquid metal filled reservoirs.

5. The electronic interconnect socket of claim 1, further including a continuous moisture barrier layer over the cap layer.

6. The electronic interconnect socket of claim 1, further including n adhesive layer between the cap layer and the array of liquid metal filled reservoirs.

7. The electronic interconnect socket of claim 1, further including an adhesive layer within a middle portion of the cap layer.

8. The electronic interconnect socket of claim 1, wherein the liquid metal includes gallium.

9. An electronic device, comprising:
a semiconductor die coupled to a first side of a substrate;
an electronic interconnect socket on a second side of the substrate, the electronic interconnect socket including;
an array of pins on a first surface;
an array of liquid metal filled reservoirs on a second surface;
a cap layer including porous resilient material regions covering the array of liquid metal filled reservoirs; and
a seal between the first surface and the second surface.

10. The electronic device of claim 9, wherein the seal includes an opposing porous resilient material located on the first surface.

11. The electronic device of claim 10, wherein the opposing porous resilient material includes a closed cell porous material.

12. The electronic device of claim 9, wherein the seal includes a moisture barrier layer on lateral edges of the cap layer.

13. The electronic device of claim 9, wherein the seal includes an array of rigid protrusions between pins in the array of pins, the array of rigid protrusions configured to compress mating portions of the cap layer when socketed.

14. The electronic device of claim 9, wherein the seal includes a first fence located on lateral edges of the first surface and a second fence located on lateral edges of the second surface, wherein the first fence and the second fence slidably fit within each other to form a moisture barrier when socketed.

15. The electronic device of claim 14, further including an array of solder balls coupled to the array of pins though the first surface.

16. The electronic device of claim 15, wherein the first fence is vertically movable with respect to the first surface.

17. The electronic device of claim 14, further including an o-ring between the first fence and the second fence when socketed.

18. A method of socketing an electronic device, comprising:
pressing a first socket half together with a second socket half, the first socket half including an array of pins and the second socket half including an array of liquid metal filled reservoirs; and
piercing a cap layer including porous resilient material regions covering the array of liquid metal filled reservoirs, wherein pores in the porous resilient material have a diameter larger than a pin cross section dimension.

19. The method of claim 18, further including compressing a portion of the porous resilient material to selectively reduce a moisture permeability.

20. The method of claim 18, further including compressing a portion of a second porous resilient material interspersed within the array of pins.

21. The method of claim 18, further including vertically sliding a first fence that surrounds the first socket half to seal against a circuit board connected to the first socket half to form a moisture barrier between the first socket half and the circuit board.

22. The method of claim 18, further including vertically sliding a second fence that surrounds the second socket half to mate with the first fence to form a moisture barrier between the first socket half and the second socket half.
